(19) United States
(12) Patent Application Publication
(10) Pub. No.: US 2023/0200252 A1
(43) Pub. Date: Jun. 22, 2023

(54) PIEZOELECTRIC SYSTEM

(71) Applicant: COMMISSARIAT A L’ENERGIE ATOMIQUE ET AUX ENERGIES ALTERNATIVES, PARIS (FR)

(72) Inventors: Gaël PILLONNET, GRENOBLE (FR); Adrien MOREL, GRENOBLE (FR); Mikhail MANOKHIN, GRENOBLE (FR)

(21) Appl. No.: 18/081,563

(22) Filed: Dec. 14, 2022

(30) Foreign Application Priority Data
Dec. 20, 2021 (FR) 2113997

(51) Int. Cl. H10N 30/80; H03H 9/17; H10N 30/87; H03H 7/38

(52) U.S. Cl. CPC H10N 30/802; H03H 9/17; H10N 30/87; H03H 7/38

(57) ABSTRACT

A piezoelectric system includes a piezoelectric resonator comprising a piezoelectric element and a pair of electrodes configured to transmit signals emitted by the piezoelectric element and generated by a deformation of the piezoelectric element; a detector configured to detect at least two signals of the signals generated by the deformation of the piezoelectric element, the at least two signals being detected at different instants; a control unit configured to compare the at least two signals and, on the basis of the comparison, determine a complex active impedance value as a function of a predetermined law; an active impedance unit configured to generate an active impedance based on the complex active impedance value determined by the control unit, the active impedance being connected to the pair of electrodes.

### CROSS-REFERENCE TO RELATED APPLICATION

This application claims priority to foreign French patent application No. FR 2113997, filed on Dec. 20, 2021, the disclosure of which is incorporated by reference in its entirety.

### FIELD OF THE INVENTION

The technical field of the present invention relates to the field of piezoelectric resonators, in particular systems comprising a piezoelectric resonator and allowing adjustment of the piezoelectric signals at the terminals of the piezoelectric resonator.

### BACKGROUND

Piezoelectric resonators make it possible to convert a movement of the resonator due to the application of a force, of a strain or of a pressure, into electrical energy. They are used in a wide range of applications such as ultrasound transducers, quartz oscillators and gyroscopes. However, the resonance effect of piezoelectric resonators is effective only over a small range of frequencies, the frequency width of which is inversely proportional to the quality factor, limiting the passband of the piezoelectric resonator. Outside of the passband, the sensitivity of piezoelectric resonators is greatly limited. The sensitivity of piezoelectric resonators is also proportional to the quality factor. Consequently, if the quality factor is high (and therefore the range of frequencies is limited), the variation of mechanical parameters such as the temperature or the ageing of the resonators, leads to a variation of the resonance frequency and/or of the passband. Furthermore, at a given excitation frequency, the resonance frequency can therefore move out of the passband and the electrical signal from the resonator is thereby greatly weakened.

There are many solutions in the state of the art. For example, it is possible to electrically adjust the resonator by implementing an additional electromechanical coupling making it possible to adjust its resonance frequency. However, the application of this additional coupling entails adding a pair of electrodes, thus limiting the active surface of the piezoelectric resonator.

Other solutions propose using a calibration of the piezoelectric resonators. However, the calibration does not allow real time optimization and therefore adaptation to sudden changes (in temperature for example).

In order to mitigate the drawbacks of the existing piezoelectric resonators, the invention proposes a piezoelectric resonator system comprising a real time servocontrolling of the parameters of the resonator without entailing the implementation of additional electrodes.

### SUMMARY OF THE INVENTION

To this end, the object of the invention is to modify the parameters of the piezoelectric resonator in order to dynamically keep the resonance frequency of the resonator close to its excitation frequency. For example, a voltage which is proportional to a force applied to the resonator can be optimized by using an active impedance applied directly to the terminals of the electrodes of the resonator. Thus, the invention makes it possible to optimise the performance of the resonator by compensating for the a priori unknown external variations, such as changes of temperature or the ageing of the resonator, without requiring an additional pair of electrodes or the addition of sensors to measure the external variations.

An active impedance is an impedance produced with “active” components, namely components of transistor or other type consuming energy in their operation in order to provide energy in the component. In other words, the active impedance is obtained with components which are not only “passive” components, of capacities, resistance or inductance type.

The invention enhances the situation by proposing a piezoelectric system comprising: a piezoelectric resonator comprising a piezoelectric element and a pair of electrodes configured to transmit signals emitted by the piezoelectric element and generated by a mechanical deformation of the piezoelectric element; a detector configured to detect at least two signals of the signals generated by the deformation of the piezoelectric element, the at least two signals being detected at different instants; a control unit configured to compare the at least two signals and, on the basis of the comparison, determine a complex active impedance value as a function of a predetermined law; an active impedance unit configured to generate an active impedance based on the complex active impedance value determined by the control unit, the active impedance being connected to the pair of electrodes.

In one embodiment, the system comprises a memory unit configured to save the at least two signals.

In one embodiment, the active impedance comprises a resistance and/or an inductance and/or a capacitance.

In one embodiment, the active impedance comprises a capacitance of negative value, an absolute value of the capacitance of negative value being less than an absolute value of an intrinsic capacitance Cp of the piezoelectric element.

In one embodiment, the active impedance unit comprises an operational amplifier.

In one embodiment, the control unit is configured to increase a capacitance value of the active impedance when a first signal of the at least two signals is greater than a second signal of the at least two signals, and reduce a capacitance value of the impedance when the first signal is less than the second signal, wherein the first signal is detected at a first instant and the second signal is detected at a second instant, the first instant preceding the second instant.

In one embodiment, the detector is configured to wait for a predetermined time between the detection of the first signal and the detection of the second signal.

Furthermore, the invention improves the situation by proposing an adjustment method for adjusting piezoelectric signals of a piezoelectric resonator comprising a piezoelectric element and a pair of electrodes configured to transmit piezoelectric signals emitted by the piezoelectric element and generated by a mechanical deformation of the piezoelectric element, the method comprising: detecting a first signal of the piezoelectric signals emitted by the piezoelectric element at an instant t; detecting a second signal of the piezoelectric signals emitted by the piezoelectric element at an instant t+1, t being different from t+1; comparing the first signal and the second signal; determining a complex active impedance value on the basis of the comparison and as a function of a predetermined law; generating an active impedance connected to the pair of electrodes, the active impedance being based on the complex active impedance value.

In one embodiment, the method is repeated successively several times and, each time the method is repeated, the first signal becomes the second signal.

In one embodiment, the method is repeated at least three times and the first signal, the second signal and a third signal are detected successively, the method comprising: stopping the method for a predetermined period when the initial signal is substantially equal to the third signal.

### BRIEF DESCRIPTION OF THE DRAWINGS

The invention will be better understood and other advantages will emerge on reading the following description given in a nonlimiting manner and from the figures in which:

FIG. 1 illustrates an example of the piezoelectric system;

FIGS. 2a, 2b, 2c and 2d illustrate examples of adjustment of piezoelectric signals of a piezoelectric resonator;

FIG. 3 illustrates an example of production of active impedance;

FIG. 4 illustrates another example of production of active impedance;

FIG. 5 illustrates another example of production of active impedance; and

FIG. 6 illustrates an example of a method for adjusting piezoelectric signals of a piezoelectric resonator.

### DETAILED DESCRIPTION

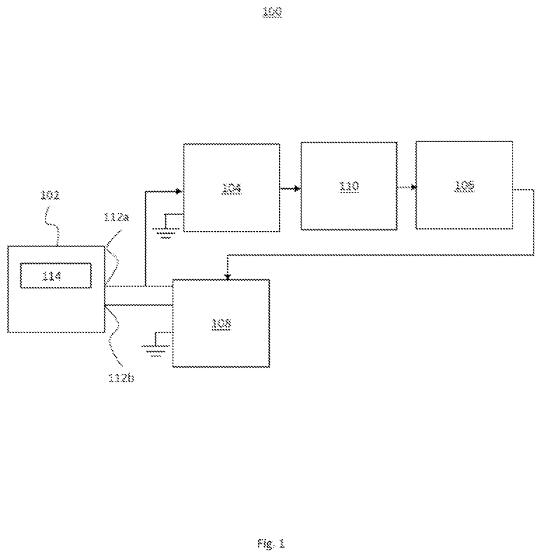

FIG. 1 illustrates a piezoelectric system 100 comprising a piezoelectric resonator 102, a detector 104, a control unit 106 and an active impedance unit 108.

The piezoelectric resonator 102 can be, for example, an ultrasound transducer, a tuning fork, a quartz oscillator or a gyroscope. The piezoelectric resonator 102 comprises a piezoelectric element 114 configured to emit signals when it is deformed. For example, the piezoelectric element 114 can comprise a beam adapted to resonate mechanically at an excitation frequency when it is subjected to a force, a pressure or a strain applied to the beam. The piezoelectric element 114 is designed to have a resonance frequency which is the eigen frequency of the passband of the piezoelectric element 114. However, the resonance frequency of the mechanical vibrations emitted by the piezoelectric element 114 depend on the forces applied but also on other factors such as:

an imprecise design of the mechanical resonator;

an ageing of the piezoelectric resonator 102, leading for example to a modification of the rigidity of the piezoelectric element 114;

variations of the ambient temperature, modifying properties of the piezoelectric element 114, and thus modifying the resonance frequency.

Consequently, in practice, since the resonance frequency varies over time, it is difficult to keep the excitation frequency close to the resonance frequency.

The piezoelectric resonator 102 converts the mechanical oscillations of the piezoelectric element 114 into electrical signals. In particular, the electrical signals form, for example, a voltage Vp which is proportional to the force applied to the piezoelectric element 114. The piezoelectric resonator 102 comprises two electrodes 112a, 112b configured to transmit the voltage Vp emitted by the piezoelectric element 114. When the excitation frequency changes, the frequency and the amplitude of the voltage Vp change also by following a curve of sensitivity of the resonator as a function of the excitation frequency.

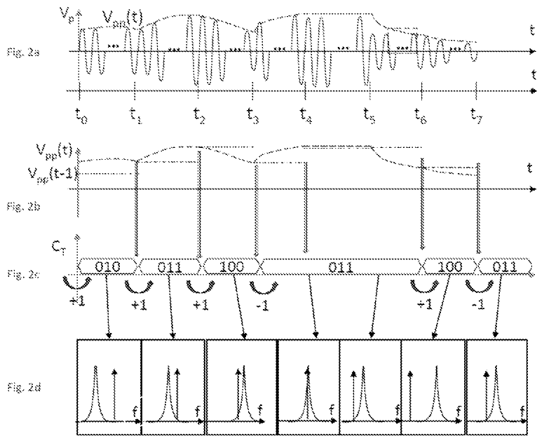

The detector 104 is configured to detect at least two signals of the signals generated by the deformation of the piezoelectric element 114, the at least two signals being detected at different instants. In particular, the detector 104 can be, for example, a detector of peak-to-peak signals which detects a peak-to-peak value Vpp of the voltage Vp present between the two electrodes 112a, 112b. The detector 104 detects the voltage Vp at different instants. For example, the detector 104 can detect the voltage Vp at an instant t and at an instant t+1. For example, FIG. 2a represents the voltage Vp and the peak-to-peak value measured at different instants. In the example illustrated in FIG. 2a, the voltage Vp is detected at instants t₀, t₂, t₃, t₄, t₅, t₆ and t₇, by the detector 104 which measures a peak-to-peak value Vpp(t) at these instants t₀, t₁, t₂, t₃, t₄, t₅, t₆ and t₇.

The detector 104 can be specifically for detecting signals used for the real time server controlling of parameters of the resonator 102. Alternatively, the detector 104 can also be used to measure the voltage Vp used for other purposes such as, for example, measurement of the excitation frequency.

The control unit 106 is configured to compare the at least two signals and, on the basis of the comparison, determine a complex active impedance value Cₜ as a function of a predetermined law. The control unit 106 can be implemented by using computing devices, software and/or a combination thereof. For example, the computing devices can be implemented using processing circuits such as, but without being limited to, a processor, a central processing unit (CPU), a controller, an arithmetic logic unit (ALU), a digital signal processor, a microcomputer, a field-programmable gate array (FPGA), a system on chip (SOC), a programmable logic unit, a microprocessor or any other device capable of responding to and executing instructions in a defined manner. The software can include a computer program, a program code, instructions, or a combination thereof, for independently or collectively instructing or configuring a hardware device for it to operate as desired. The computer program and/or the program code can comprise program or computer-readable instructions, software components, software modules, data files, data structures and/or the like, that can be implemented by one or more hardware devices, such as one or more of the hardware peripheral devices mentioned above. When a hardware device is a computer processing device (for example, CPU, controller, ALU, digital signal processor, microcomputer, microprocessor, etc.), the computer processing device can be configured to execute a program code by performing arithmetic, logic and input/output operations, according to the program code.

For example, the control unit 106 receives at least two peak-to-peak values Vpp(t) from the detector 104 and compares the values received. For example, as indicated above and illustrated in FIG. 2a, the detector 104 detects peak-to-peak values Vpp(t) at the instants t₀, t₁, t₂, t₃, t₄, t₅, t₆ and t₇. As illustrated in FIG. 2b, the control unit 106 compares the peak-to-peak value Vpp(t₋₁) to the peak-to-peak value Vpp(t₀). In fact, the first value of Vpp(t) in FIG. 2b indicates that a value Vpp(t₋₁) was measured at an instant t₋₁. Likewise, the control unit 106 compares the peak-to-peak value Vpp(t₋₁) to the peak-to-peak value Vpp(t₁), the peak-to-peak value Vpp(t₁) to the peak-to-peak value Vpp(t₂) . . . and the peak-to-peak value Vpp(t₅) to the peak-to-peak value Vpp(t₆).

As illustrated in FIG. 2b, the control unit 106 is configured to wait for a time allowing the voltage Vp to be stabilized before comparing the peak-to-peak values at two different instants. In fact, that allows the piezoelectric resonator 102 to achieve a steady state before comparing the values of signals detected.

The control unit 106 is also configured to determine a complex active impedance value C_{T} as a function of a predetermined law on the basis of the comparison. Furthermore, the active impedance unit 108 is configured to generate an active impedance C_{T} based on the complex active impedance value C_{T} determined by the control unit 106. The active impedance is then applied to the piezoelectric resonator 102 by the pair of electrodes 112a, 112b which is connected to the active impedance unit 108. In practice, the active impedance is combined with the intrinsic impedance of the resonator 102 seen between the two electrodes 112a, 112b. The combining of the two impedances can be done by serial or parallel connection of the two impedances. Thus, an active impedance is applied to the piezoelectric resonator 102 in order to modify the parameters of the resonator, for example to modify the voltage Vp.

The predetermined law can be applied by an algorithm which determines the complex active impedance value C_{T} by successive tests and iteration. For example, the predetermined law can depend for example on the piezoelectric resonator 102 or be based on a mapping table containing predetermined values. In particular, the predetermined law can minimize or maximize the voltage Vp or make the voltage Vp greater than a predetermined value in order to modulate the sensitivity of the sensor to the excitation frequency. For example, a transfer function comprising a relationship between the voltage Vp and an external mechanical excitation on the piezoelectric element can be determined and maximized. For example, the predetermined law can be executed by an algorithm which determines an active impedance value C_{T} greater than the preceding value when the peak-to-peak value at a first instant is less than the peak-to-peak value at a second instant. Similarly, the algorithm can determine an active impedance value C_{T} less than the preceding value when the peak-to-peak value at a first instant is greater than the peak-to-peak value at a second instant. Generally, as illustrated in FIG. 2c, the active impedance unit 108 is configured to increment the active impedance C_{T} in one direction or decrement the active impedance C_{T} in the other direction, depending on the comparison between the peak-to-peak values at two instants.

In considering for example the comparison between the peak-to-peak value Vpp at the instant to and the peak-to-peak value Vpp at the instant t₁, the control unit 106 determines that the peak-to-peak value Vpp(t₀) is less than the peak-to-peak value Vpp(t₁). Thus, the control unit 106 determines a complex active impedance value C_{T} transmitted to the active impedance unit 108 which, when applied to the piezoelectric resonator 102 by the active impedance unit 108, modifies the value Vp. Since the control unit 106 determines that the peak-to-peak value Vpp at the instant to is less than the peak-to-peak value Vpp at the instant t₁, that indicates that the voltage Vp at the instant to is not maximized.

FIG. 2d represents graphs of the amplitude of the voltage Vp as a function of the frequency at instants t₀ to t₇. In each graph, the excitation frequency is represented by a vertical arrow, and the resonance frequency is represented by a curve of gaussian type in which the resonance frequency is embodied by the top of the curve.

As illustrated in FIG. 2d, the resonance and excitation frequencies can differ. It may be desirable to bring these two frequencies closer together in order to maximize the voltage Vp. In order to maximize the voltage Vp at the instant t₁, the control unit 106 considers that, if the value Vpp at an instant to is less than that at an instant t₁, the control unit 106 increments the active impedance value C_{T} in one direction. In the example of FIG. 2c, the active impedance value C_{T} is incremented in the same direction as the active impedance value C_{T} which was applied to the piezoelectric resonator 102 at the instant to. For example, at the instant an active impedance value C_{T} greater than that at the instant to can be applied to the piezoelectric resonator 102. The increments represented in FIG. 2c represent binary values associated with active impedance values. The step between two successive increments can for example be regular.

Similarly, since the control unit 106 determines that the peak-to-peak value Vpp(t₁) is less than the peak-to-peak value Vpp(t₂), as illustrated in FIG. 2d, the voltage Vp is not maximized between the instants t₁ and t₂ because the excitation frequency and the resonance frequency differ. Thus, the control unit 106 increments the active impedance value C_{T} in the same direction as the active impedance value C_{T} which was applied to the piezoelectric resonator 102 at the instant t₁. For example, at the instant t₂, an active impedance value C_{T} greater than that at the instant to can be applied to the piezoelectric resonator 102.

However, as indicated in FIG. 2b, the peak-to-peak value Vpp(t₂) is greater than the peak-to-peak value Vpp(t₁). The lowering of the peak-to-peak value Vpp indicates that the optimal value of Vp has been exceeded. Thus, the control unit 106 increments the active impedance value in the direction opposite to that which was applied to the piezoelectric resonator 102 at the instant t₂. For example, at the instant t₃, an active impedance value C_{T} greater than that at the instant t₂ can be applied to the piezoelectric resonator 102. Thus, as indicated in FIG. 2d, when the value Vp is maximized, the value of the excitation frequency is equal to the resonance frequency of the piezoelectric element.

Since the maximum value Vp is reached, the control unit 106 can cease to determine an active impedance value C_{T} when the signals remain constant. Alternatively, the detector 104 can be configured to wait for a predetermined time between the detection of another signal. The detector 104 can be stopped for example. Similarly, the control unit 106 can also be stopped for the same predetermined time. Thus, the system 100 can be paused for a time while the value Vp is maximal. The predetermined time can be based on the type of piezoelectric resonator 102 for example.

In another example, as indicated above, instead of centring the resonance frequency on the excitation frequency, it is possible to maximize a transfer function comprising a relationship between the voltage Vp and an external mechanical excitation on the piezoelectric element.

In other example, instead of determining discrete active impedance values C_{T}, as indicated above, the control unit 106 can determine continuous active impedance values. For example, the control unit 106 can determine a range of values and the active impedance unit 108 can generate active impedance within this range.

As indicated in FIG. 2d, when the voltage Vp is modified by the application of the active impedance, the resonance frequency is modified. In order to optimize the resonator, the resonance frequency must be close to the excitation frequency. At the instant t₅, the excitation frequency can once again differ from the resonance frequency, without changing the active impedance. This change can be generated for example by a change of temperature or the ageing of the piezoelectric resonator 102. When a change occurs, the control unit 106 determines a new active impedance value C_{T} which is applied to the piezoelectric resonator 102 and the process is repeated until the value Vp is once again maximal.

Thus, as indicated in FIG. 2b, the peak-to-peak value Vpp(t₅) is compared to the peak-to-peak value Vpp(t₆) and a new active impedance is applied to the piezoelectric resonator 102 in order to once again maximize the voltage Vp.

Furthermore, the process carried out by the system 100 described above can be repeated in order to maximize the value Vp in real time and to keep the resonance frequency close to the excitation frequency. That makes it possible to maximize the sensitivity of the piezoelectric resonator 102 which has been brought closer to the excitation frequency, and thus optimize the operation of the piezoelectric resonator 102 as a function of factors such as changes of temperature and ageing. The optimizing can be carried out in real time and without doing any calibration. Furthermore, it should be noted that, in the above examples, the application of an active impedance to the piezoelectric resonator 102 by the pair of electrodes 112a, 112b modifies the overall resonance frequency (including the eigen frequency and an electrical impedance) as well as the quality factor of the piezoelectric resonator 102.

Optionally, the piezoelectric system 100 comprises a memory unit 110 configured to save the at least two signals. The control unit 106 can also comprise one or more storage devices such as the memory unit 110. The storage device or devices can be tangible or non-transient computer-readable storage media, such as a random-access memory (RAM), a read-only memory (ROM), a permanent mass storage device (such as a disk drive), a non-volatile storage device (NAND flash for example) and/or any other similar data storage mechanism capable of storing and saving data. Furthermore, the storage device or devices can correspond to accesses to remote computing services via an internet network, known by the term “cloud”. The storage device or devices can be configured to store computer programs, a program code, instructions or a combination thereof, for one or more operating systems and/or to implement the exemplary embodiments described here. The computer programs, the program code, the instructions or a combination thereof can also be loaded from a separate computer-readable storage medium into the storage device or devices and/or one or more computer processing devices using a drive mechanism. Such a separate computer-readable storage medium can comprise a USB (Universal Serial Bus) key, a memory key, a Blu-ray/DVD/CD-ROM drive, a memory card and/or other computer-readable storage media.

For example, the detector can transmit the detected peak-to-peak value Vpp to the memory 110 after each detection. The memory 110 can then transmit the Vpp values to the control unit 106 which then runs the comparison between the Vpp values.

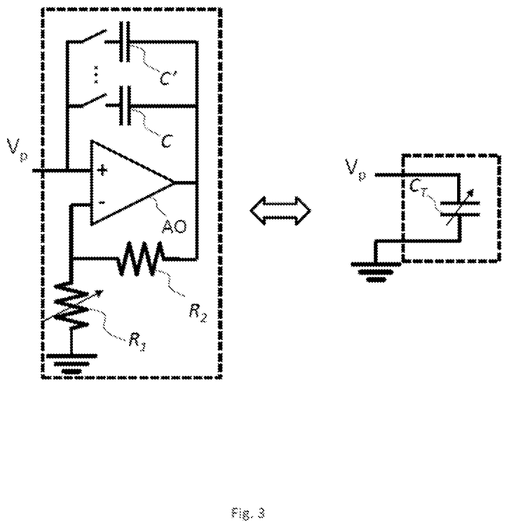

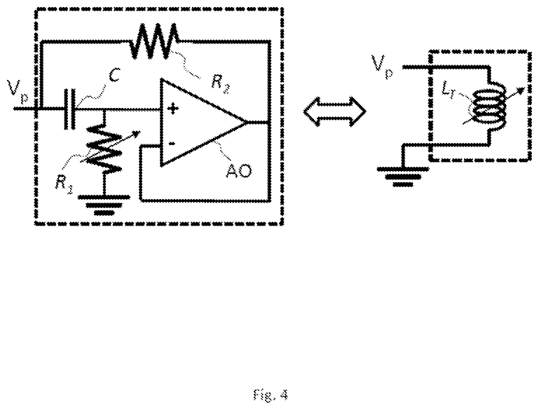

Two examples of active impedance units 108 are illustrated in FIGS. 3 and 4. The active impedance unit 108 comprises a resistance and/or an inductance and/or a capacitance. In particular, the active impedance can be generated by a capacitance of negative value C_{T} or a positive inductance L_{T}.

FIG. 3 represents an example of active impedance unit 108 configured to allow the generation of an active impedance with a capacitance of negative value C_{T}. In this example, the active inductance comprises a variable resistor R₁, a resistor R₂, an operational amplifier AO, a capacitor of value C and a capacitor of value C′ forming a bank of capacitors arranged in parallel, and in which C′=2^{N}×C. The piezoelectric element 114 comprises an intrinsic piezoelectric impedance comprising a capacitance Cp. The stability of the system is ensured when the capacitance C is less than the capacitance Cp. To change the capacitance value of the active impedance applied to the piezoelectric resonator 102, the value of the variable resistor R₁ is changed. The variable resistor can be, for example, a transistor whose gate is modulated by analogue means. For example, the control unit 106, in determining the active impedance value C_{T}, can determine the value of the variable resistor R₁ by using the relationship:

$${C}_{T} = - \frac{{R}_{1}}{{R}_{2}} C .$$

Thus, in order to optimize the performance of the resonator, the capacitance C_{T} can advantageously vary from −C_{P} to 0.

Furthermore, as indicated above, the value of the resistance can be changed in order to obtain active impedance values that are discrete or continuous, that is to say continuous values within a range determined by the control unit 106.

Thus, as indicated in FIG. 3, the configuration illustrated simulates a capacitance of variable negative values which makes it possible to change the voltage Vp.

FIG. 4 represents another example of active impedance unit 108 configured to generate an active impedance with a positive inductance Li. The configuration of FIG. 4 is that of a gyrator system comprising a variable resistor R₁, a capacitor C, an operational amplifier and a resistor R₂. To change the capacitance value of the active impedance applied to the piezoelectric resonator 102, the value of the variable resistor R₁ is changed. For example, the control unit 108, in determining the active impedance value, can determine the value of the variable resistor R₁ by using the relationship: L_{T}=CR₁R₂.

Furthermore, as indicated above, the value of the resistor can be changed in order to obtain active impedance values C_{T} that are discrete or continuous, that is to say continuous values within a range determined by the control unit 106.

Thus, as indicated in FIG. 4, the configuration illustrates simulates a variable positive inductance which makes it possible to change the voltage V_{P} by being combined with the intrinsic impedance C_{P} of the piezoelectric element 114.

The examples of active impedance units 108 described above make it possible to generate an impedance intended for example to maximize the voltage Vp, directly at the terminals of the electrodes 112a, 112b of the piezoelectric resonator 102. In particular, the present invention does not require the use of additional electrodes that are necessary for the inventions that use passive elements such as “varicaps” (diodes with capacitances that are variable as a function of a voltage applied to the terminals). Thus, the present invention makes it possible to maximize the surface of the piezoelectric element 114.

Furthermore, the examples described above allow the application of an impedance ranging beyond the cancellation of the electrical capacitance Cp linked to the piezoelectric element 114. Thus, the present invention allows a wider variation of the voltage Vp.

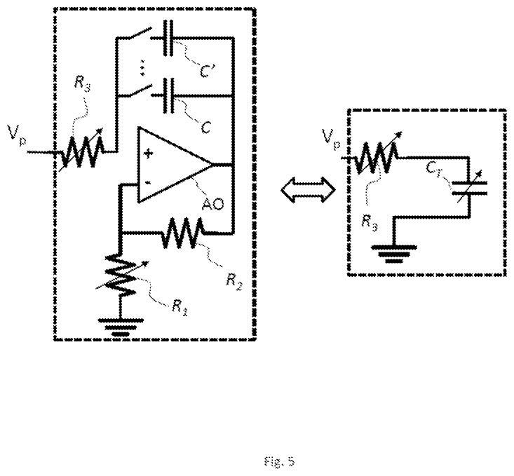

Alternatively, the active impedance unit 108 of FIG. 3 or of FIG. 4 can generate two active impedances simultaneously or sequentially in order to adapt the resonance frequency and the quality factor. For example, as illustrated in FIG. 5, a variable resistance R₃ and an active impedance C_{T} can be used to modify the quality factor and the resonance frequency. The resistance R₃ illustrated in FIG. 5 is a positive resistance that makes it possible to modify the quality factor and adapt the resonance frequency. In another example, a circuit configured to generate a negative resistance can be used, which would make it possible to modify the quality factor and the resonance frequency. Alternatively, two active impedance units can be used, one generating an active impedance that makes it possible to maximize the quality factor, the other generating an active impedance that makes it possible to adapt the resonance frequency.

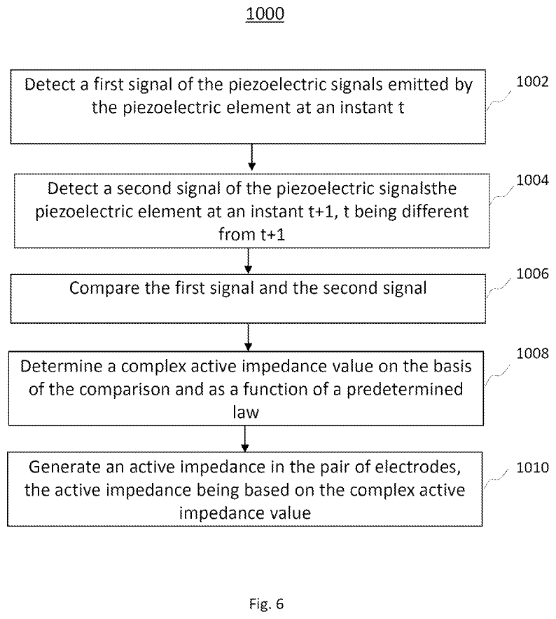

FIG. 6 is a flow diagram illustrating an adjustment method 1000 for adjusting piezoelectric signals of a piezoelectric resonator 102 comprising a piezoelectric element 114 and a pair of electrodes 112a, 112b configured to transmit piezoelectric signals emitted by the piezoelectric element 114 and generated by a mechanical deformation of the piezoelectric element 114. For example, the method 1000 can be implemented by the system 100 described above.

In the step 1002, a first signal of the piezoelectric signals emitted by the piezoelectric element 114 is detected at an instant t. For example, as illustrated in FIG. 2a, the signal Vp(t) is detected at the instant t and the peak-to-peak value Vpp(t) is measured.

In the step 1004, a second signal of the piezoelectric signals emitted by the piezoelectric element 114 is detected at an instant t, t being different from t+1. For example, as illustrated in FIG. 2a, the signal Vp(t+1) is detected at the instant t+1 and the peak-to-peak value Vpp(t+1) is measured.

In the step 1006, the first signal and the second signal are compared. For example, as illustrated in FIG. 2b, the peak-to-peak value Vpp(t+1) is greater than the peak-to-peak value Vpp(t).

In the step 1008, a complex active impedance value C_{T} is determined on the basis of the comparison and as a function of a predetermined law. In the step 1010, an active impedance is generated in the pair of electrodes 112a, 112b, the active impedance being based on the complex active impedance value C_{T}. As illustrated in FIG. 2c, a complex active impedance value 100 is determined and applied to the piezoelectric resonator 102 in order to modify the voltage Vp.

The adjust method 1000 can be repeated successively several times and, each time the method 1000 is repeated, the second signal becomes the first signal. For example, as indicated above, with respect to FIG. 2b, the peak-to-peak voltages Vpp(t) and Vpp(t+1) are compared. Since Vpp(t1) is greater than Vpp(t), the control unit 106 determines a complex impedance value C_{T} in order to maximize the value of the voltage Vp. Once the impedance C_{T} is generated and applied to the piezoelectric resonator 102, the peak-to-peak voltages Vpp(t+1) and Vpp(t+2) are compared, and so on.

In one example, the adjustment method 1000 is repeated at least three times and the first signal, the second signal and a third signal are detected successively and the method is stopped for a predetermined period when the initial first signal is substantially equal to the third signal (within a tolerance threshold). For example, as illustrated in FIG. 2a, the method 1000 is carried out several times. Specifically, an active impedance 011 was applied to the piezoelectric resonator 102 in order to obtain the peak-to-peak value Vpp(t+3). Then, an active impedance 100, less than the active impedance 011, was applied to the piezoelectric resonator 102 in order to obtain the peak-to-peak value Vpp(t+4). However, the peak-to-peak value Vpp(t+4) is less than the peak-to-peak value Vpp(t+3). Therefore, the active impedance 011 is once again applied to the piezoelectric resonator 102. The peak-to-peak value Vpp(t+3) is equal to the peak-to-peak value Vpp(t+4). Thus, the voltage Vp(t+4) is optimized with the active impedance 011. Consequently, the system can be stopped for a time which can for example depend on the piezoelectric resonator 102 or be indicated by an operator.

Although the invention has been illustrated and described in detail using a preferred embodiment, the invention is not limited to the examples disclosed. Other variants can be deduced by the person skilled in the art without departing from the scope of protection of the claimed invention.

1. A piezoelectric system comprising:
a piezoelectric resonator comprising a piezoelectric element and a pair of electrodes configured to transmit signals emitted by the piezoelectric element and generated by a mechanical deformation of the piezoelectric element;
a detector configured to detect at least two signals of the signals generated by the deformation of the piezoelectric element, the at least two signals being detected at different instants;
a control unit configured to compare the at least two signals and, on the basis of the comparison, determine a complex active impedance value as a function of a predetermined law;
an active impedance unit configured to generate an active impedance based on the complex active impedance value determined by the control unit, the active impedance being connected to the pair of electrodes.

2. The piezoelectric system according to claim 1, wherein the system comprises a memory unit configured to save the at least two signals.

3. The piezoelectric system according to claim 1, wherein the active impedance comprises a resistance and/or an inductance and/or a capacitance.

4. The piezoelectric system according to claim 1, wherein the active impedance comprises a capacitance of negative value, an absolute value of the capacitance of negative value being less than an absolute value of an intrinsic capacitance Cp of the piezoelectric element.

5. The piezoelectric system according to claim 1, wherein the active impedance unit comprises an operational amplifier.

6. The piezoelectric system according to claim 1, wherein the control unit is configured to increase a capacitance value of the active impedance when a first signal of the at least two signals is greater than a second signal of the at least two signals, and reduce a capacitance value of the impedance when the first signal is less than the second signal, wherein the first signal is detected at a first instant and the second signal is detected at a second instant, the first instant preceding the second instant.

7. The piezoelectric system according to claim 1, wherein the detector is configured to wait for a predetermined time between the detection of the first signal and the detection of the second signal.

8. An adjustment method for adjusting piezoelectric signals of a piezoelectric resonator comprising a piezoelectric element and a pair of electrodes configured to transmit piezoelectric signals emitted by the piezoelectric element and generated by a mechanical deformation of the piezoelectric element, the method comprising:
detecting a first signal of the piezoelectric signals emitted by the piezoelectric element at an instant t;
detecting a second signal of the piezoelectric signals emitted by the piezoelectric element at an instant t+1, t being different from t+1;
comparing the first signal and the second signal;
determining a complex active impedance value on the basis of the comparison and as a function of a predetermined law; and
generating an active impedance connected to the pair of electrodes, the active impedance being based on the complex active impedance value.

9. The adjustment method according to claim 8, wherein the method is repeated successively several times and, each time the method is repeated, the first signal becomes the second signal.

10. The adjustment method according to claim 9, wherein the method is repeated at least three times and the first signal the second signal and a third signal are detected successively, the method comprising:
stopping the method for a predetermined period when the initial signal is substantially equal to the third signal.
